(19) United States
(12) Patent Application Publication
(10) Pub. No.: US 2023/0408901 A1
(43) Pub. Date: Dec. 21, 2023

(54) OPTICAL PROXIMITY CORRECTION FOR FREE FORM SHAPES

(71) Applicant: Siemens Industry Software Inc., Plano, TX (US)

(72) Inventors: George P. Lippincott, Lake Oswego, OR (US); Vladislav Liubich, West Linn, OR (US); Kyohei Sakajiri, Portland, OR (US)

(21) Appl. No.: 18/029,211

(22) PCT Filed: Oct. 8, 2020
(86) PCT No.: PCT/US2020/054724

§ 371 Date: Mar. 29, 2023

(51) Int. Cl. G03F 1/36; G06F 30/392

(52) U.S. Cl. CPC G03F 1/36; G06F 30/392

(57) ABSTRACT

Aspects of the disclosed technology relate to techniques for applying optical proximity correction to free form shapes. Each optical proximity correction iteration comprises: computing edge adjustment values for the straight ty correction iteration immediately preceding the each of the plurality of optical proximity correction iterations, adjusting locations of the straight line fragments based on the determined edge adjustment values, determining smooth boundary lines for the layout features based on the straight line fragments on the adjusted locations, performing a simulation process on the layout features having the smooth boundary lines to determine a simulated image of the layout features, and deriving the edge adjustment errors for the straight line fragments based on comparing the simulated image with a target image of the layout features.

### FIELD OF THE DISCLOSED TECHNOLOGY

The present disclosed technology relates to the field of circuit design and manufacture. Various implementations of the disclosed technology may be particularly useful for optical proximity correction of layout designs.

### BACKGROUND OF THE DISCLOSED TECHNOLOGY

As designers and manufacturers continue to shrink the size of circuit components, the shapes reproduced on the substrate though photolithography become smaller and are placed closer together. This reduction in feature size and spacing increases the difficulty of faithfully reproducing the image onto the substrate intended by the design layout and can create flaws in the manufactured device. To address the problem, one or more resolution enhancement techniques are often employed to improve the resolution of the image that the mask forms on the substrate during the photolithographic process.

One of resolution enhancement techniques, “optical proximity correction” or “optical process correction” (OPC), tries to compensate for light diffraction effects. When light illuminates the photomask, the transmitted light diffracts. The higher spatial frequencies the regions of the mask have, the higher angles the light diffracts at. The resolution limits of the lens in a photolithographic system make the lens act effectively as a low-pass filter for the various spatial frequencies in the two-dimensional layout. This can lead to optical proximity effects such as a pull-back of line-ends from their desired position, corner rounding and a bias between isolated and dense structures. The optical proximity correction adjusts the amplitude of the light transmitted through a lithographic mask by modifying the layout design data employed to create the photomask. For example, edges in the layout design may be adjusted to make certain portions of the geometric elements larger or smaller, in accordance with how much additional light exposure (or lack of exposure) is desired at certain points on the substrate. When these adjustments are appropriately calibrated, overall pattern fidelity is greatly improved, thereby reducing optical proximity effects.

Typically, a layout design contains mainly Manhattan shapes. For Manhattan shapes, edges are parallel to the x and y axes. Conventional design rule checking (DRC) and OPC tools focus on processing Manhattan shapes. Silicon photonics, combining large-scale photonic integration with large-scale electronic integration, can impact areas such as telecommunications, data centers and high-performance computing. Silicon photonics designs, however, are often drawn with curved shapes. Curvilinear patterns also could offer better lithographic quality than Manhattan patterns. Memory chip making has started to explore curvilinear patterns. Due to the practical needs and advantages for using curvilinear patterns, the mask making industry has made progress with the introduction of multi-beam mask writers for writing curvilinear patterns on a mask. OPC techniques, however, still need to be improved for better processing curvilinear shapes.

### BRIEF SUMMARY OF THE DISCLOSED TECHNOLOGY

Aspects of the disclosed technology relate to techniques for applying optical proximity correction to free form shapes. In one aspect, there is a method comprising: fragmenting boundary lines of layout features in a layout design into straight line fragments, the fragmenting comprising using some of the straight line fragments to represent curved boundary line segments of the layout features; generating modified layout features based on a plurality of optical proximity correction iterations, each of the plurality of optical proximity correction iterations comprising: computing edge adjustment values for the straight line fragments based on edge placement errors derived from an optical proximity correction iteration immediately preceding the each of the plurality of optical proximity correction iterations, adjusting locations of the straight line fragments based on the determined edge adjustment values, determining smooth boundary lines for the layout features based on the straight line fragments on the adjusted locations, performing a simulation process on the layout features having the smooth boundary lines to determine a simulated image of the layout features, and deriving the edge adjustment errors for the straight line fragments based on comparing the simulated image with a target image of the layout features.

The method may further comprise: processing the modified layout features to generate mask data for a mask-writing tool to make photomasks. The method may still further comprise: applying the mask data to the mask-writing tool to create photomasks.

The determining smooth boundary lines may be based on a Gaussian convolution technique. Lengths of the straight line fragments may be greater than or equal to one fourth of minimum feature size of the layout design. Each of the straight line fragments may be parallel to either the x axis or the y axis of the layout design. The computing edge adjustment values may comprise multiplying the edge placement errors by a matrix including cross-mask error enhancement factors.

The plurality of optical proximity correction iterations may be terminated when the edge adjustment errors are within a predetermined range or a number of the plurality of optical proximity correction iterations is equal to a predetermined number.

In another aspect, there is one or more computer-readable media storing computer-executable instructions for causing one or more processors to perform the above method.

In still another aspect, there is a system, comprising: one or more processors, the one or more processors programmed to perform the above method.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed technology. Thus, for example, those skilled in the art will recognize that the disclosed technology may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a computing system that may be used to implement various embodiments of the disclosed technology.

FIG. 2 illustrates an example of a multi-core processor unit that may be used to implement various embodiments of the disclosed technology.

FIG. 3A illustrates a mask feature 300 and a simulated image 302 of the mask feature;

FIG. 3B illustrates an example of fragmentation of an edge of the mask feature 300;

FIG. 3C illustrates edge displacement errors for some of the edge fragments; FIG. 3D illustrates a mask feature modified 303 from the mask feature 300 by an OPC process and a corresponding simulated image 304.

FIG. 4 illustrates two curvilinear shapes of which the boundary lines are fragmented.

FIG. 5 illustrates an example of waviness caused by using straight line segments to approximate curved boundary lines.

FIG. 6 illustrates an example of an optical proximity correction tool that may be implemented according to various embodiments of the disclosed technology.

FIG. 7 illustrates a flowchart showing a process of optical proximity correction that may be implemented according to various examples of the disclosed technology.

FIG. 8 illustrates an example of part of a curvilinear layout feature which are fractured for OPC treatment using two different approaches.

FIG. 9 illustrates an example of optical proximity iterations according to various examples of the disclosed technology.

FIG. 10A illustrates an example of a smoothing result for a layout feature derived via Gaussian convolution during an OPC iteration.

FIG. 10B illustrates an example of a modified layout feature obtained by performing an OPC process on the layout feature shown in FIG. 10A according to various examples of the disclosed technology.

### DETAILED DESCRIPTION OF THE DISCLOSED TECHNOLOGY

General Considerations

Various aspects of the present disclosed technology relate to techniques for applying optical proximity correction to free form shapes. In the following description, numerous details are set forth for the purpose of explanation. However, one of ordinary skill in the art will realize that the disclosed technology may be practiced without the use of these specific details. In other instances, well-known features have not been described in detail to avoid obscuring the present disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods. Additionally, the detailed description sometimes uses terms like “perform”, “derive”, and “determine” to describe the disclosed methods. Such terms are high-level abstractions of the actual operations that are performed. The actual operations that correspond to these terms will vary depending on the particular implementation and are readily discernible by one of ordinary skill in the art.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one micro device, such as data to be used to form multiple micro devices on a single wafer.

Illustrative Operating Environment

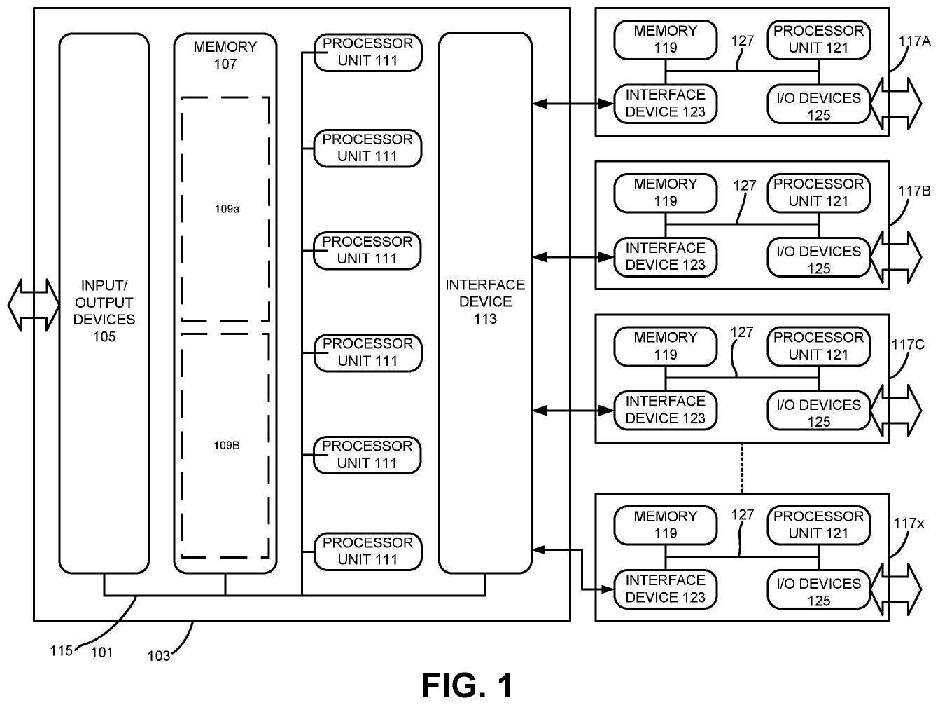

The execution of various electronic design automation processes according to embodiments of the disclosed technology may be implemented using computer-executable software instructions executed by one or more programmable computing devices. Because these embodiments of the disclosed technology may be implemented using software instructions, the components and operation of a generic programmable computer system on which various embodiments of the disclosed technology may be employed will first be described. Further, because of the complexity of some electronic design automation processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the disclosed technology.

In FIG. 1, the computer network 101 includes a master computer 103. In the illustrated example, the master computer 103 is a multi-processor computer that includes a plurality of input and output devices 105 and a memory 107. The input and output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the disclosed technology. Accordingly, the memory 107 stores software instructions 109A that, when executed, will implement a software application for performing one or more operations. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

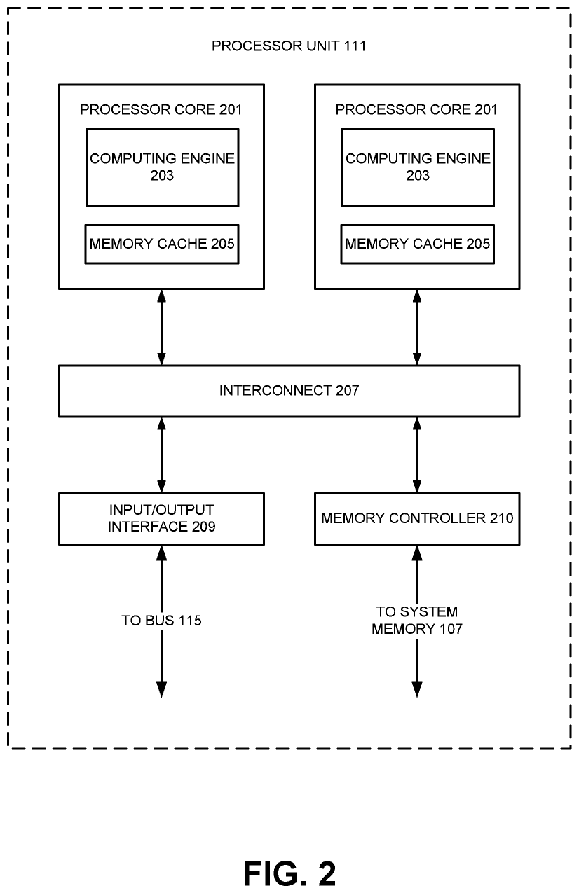

With some implementations of the disclosed technology, the master computing device 103 may employ one or more processing units 111 having more than one processor core. Accordingly, FIG. 2 illustrates an example of a multi-core processor unit 111 that may be employed with various embodiments of the disclosed technology. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 111. With some processor cores 201, such as the Cell microprocessor created by Sony Corporation, Toshiba Corporation and IBM Corporation, the interconnect 207 may be implemented as an interconnect bus. With other processor units 111, however, such as the Opteron™ and Athlon™ dual-core processors available from Advanced Micro Devices of Sunnyvale, California, the interconnect 207 may be implemented as a system request interface device. In any case, the processor cores 201 communicate through the interconnect 207 with an input/output interface 209 and a memory controller 210. The input/output interface 209 provides a communication interface between the processor unit 111 and the bus 115. Similarly, the memory controller 210 controls the exchange of information between the processor unit 111 and the system memory 107. With some implementations of the disclosed technology, the processor units 111 may include additional components, such as a high-level cache memory accessible shared by the processor cores 201.

While FIG. 2 shows one illustration of a processor unit 111 that may be employed by some embodiments of the disclosed technology, it should be appreciated that this illustration is representative only, and is not intended to be limiting. Also, with some implementations, a multi-core processor unit 111 can be used in lieu of multiple, separate processor units 111. For example, rather than employing six separate processor units 111, an alternate implementation of the disclosed technology may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. For example, with some implementations of the disclosed technology, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the disclosed technology may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the disclosed technology, either the computer 103, one or more of the servant computers 117, or some combination of both may use two or more different interface devices 113 or 123 for communicating over multiple communication interfaces.

With various examples of the disclosed technology, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the disclosed technology, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the disclosed technology.

Circuit Design Flow and Optical Proximity Correction

Electronic circuits, such as integrated microcircuits, are used in a variety of products, from automobiles to microwaves to personal computers. Designing and fabricating integrated circuit devices typically involves many steps, sometimes referred to as a “design flow.” The particular steps of a design flow often are dependent upon the type of integrated circuit, its complexity, the design team, and the integrated circuit fabricator or foundry that will manufacture the microcircuit. Typically, software and hardware “tools” verify the design at various stages of the design flow by running software simulators and/or hardware emulators. These steps aid in the discovery of errors in the design, and allow the designers and engineers to correct or otherwise improve the design.

Several steps are common to most design flows. Initially, the specification for a new circuit is transformed into a logical design, sometimes referred to as a register transfer level (RTL) description of the circuit. With this logical design, the circuit is described in terms of both the exchange of signals between hardware registers and the logical operations that are performed on those signals. The logical design typically employs a Hardware Design Language (HDL), such as the Very high speed integrated circuit Hardware Design Language (VHDL). The logic of the circuit is then analyzed, to confirm that it will accurately perform the functions desired for the circuit. This analysis is sometimes referred to as “functional verification.”

After the accuracy of the logical design is confirmed, it is converted into a device design by synthesis software. The device design, which is typically in the form of a schematic or netlist, describes the specific electronic devices (such as transistors, resistors, and capacitors) that will be used in the circuit, along with their interconnections. This device design generally corresponds to the level of representation displayed in conventional circuit diagrams. The relationships between the electronic devices are then analyzed, to confirm that the circuit described by the device design will correctly perform the desired functions. This analysis is sometimes referred to as “formal verification.” Additionally, preliminary timing estimates for portions of the circuit are often made at this stage, using an assumed characteristic speed for each device, and incorporated into the verification process.

Once the components and their interconnections are established, the design is again transformed, this time into a physical design that describes specific geometric elements. This type of design often is referred to as a “layout” design. The geometric elements, which typically are polygons, define the shapes that will be created in various layers of material to manufacture the circuit. Typically, automated place and route tools will be used to define the physical layouts, especially of wires that will be used to interconnect the circuit devices. Each layer of the microcircuit will have a corresponding layer representation in the layout design, and the geometric shapes described in a layer representation will define the relative locations of the circuit elements that will make up the circuit device. For example, shapes in the layer representation of a metal layer will define the locations of the metal wires used to connect the circuit devices. Custom layout editors, such as Mentor Graphics' IC Station or Cadence's Virtuoso, allow a designer to custom design the layout, which is mainly used for analog, mixed-signal, RF, and standard-cell designs.

Integrated circuit layout descriptions can be provided in many different formats. The Graphic Data System II (GDSII) format is a popular format for transferring and archiving two-dimensional graphical IC layout data. Among other features, it contains a hierarchy of structures, each structure containing layout elements (e.g., polygons, paths or poly-lines, circles and textboxes). Other formats include an open source format named Open Access, Milkyway by Synopsys, Inc., EDDM by Mentor Graphics, Inc., and the more recent Open Artwork System Interchange Standard (OASIS) proposed by Semiconductor Equipment and Materials International (SEMI). These various industry formats are used to define the geometrical information in IC layout designs that are employed to manufacture integrated circuits. Once the microcircuit device design is finalized, the layout portion of the design can be used by fabrication tools to manufacture the device using a photolithographic process.

Typically, a designer will perform a number of verification processes on the layout design. For example, the layout design may be analyzed to confirm that it accurately represents the circuit devices and their relationships described in the device design. In this process, a LVS (layout versus schematic) tool extracts a netlist from the layout design and compares it with the netlist taken from the circuit schematic. LVS can be augmented by formal equivalence checking, which checks whether two circuits perform exactly the same function without demanding isomorphism.

The layout design also may be analyzed to confirm that it complies with various design requirements, such as minimum spacings between geometric elements and minimum linewidths of geometric elements. In this process, a DRC (design rule checking) tool takes as input a layout in the GDSII standard format and a list of rules specific to the semiconductor process chosen for fabrication. A set of rules for a particular process is referred to as a run-set, rule deck, or just a deck. An example of the format of a rule deck is the Standard Verification Rule Format (SVRF) by Mentor Graphics Corporation.

There are many different fabrication processes for manufacturing a circuit, but most processes include a series of steps that deposit layers of different materials on a substrate, expose specific portions of each layer to radiation, and then etch the exposed (or non-exposed) portions of the layer away. For example, a simple semiconductor device component could be manufactured by the following steps. First, a positive type epitaxial layer is grown on a silicon substrate through chemical vapor deposition. Next, a nitride layer is deposited over the epitaxial layer. Then specific areas of the nitride layer are exposed to radiation, and the exposed areas are etched away, leaving behind exposed areas on the epitaxial layer, (i.e., areas no longer covered by the nitride layer). The exposed areas then are subjected to a diffusion or ion implantation process, causing dopants, for example phosphorus, to enter the exposed epitaxial layer and form charged wells. This process of depositing layers of material on the substrate or subsequent material layers, and then exposing specific patterns to radiation, etching, and dopants or other diffusion materials, is repeated a number of times, allowing the different physical layers of the circuit to be manufactured.

Each time that a layer of material is exposed to radiation, a mask must be created to expose only the desired areas to the radiation, and to protect the other areas from exposure. The mask is created from circuit layout data. That is, the geometric elements described in a design layout define the relative locations or areas of the circuit that will be exposed to radiation through the mask. A mask or reticle writing tool is used to create the mask based upon the design layout, after which the mask can be used in a photolithographic process.

As discussed previously, one or more resolution enhancement techniques (RETs) are often employed to improve the resolution of the image that the mask forms on the substrate during the photolithographic process. One of these techniques is optical proximity correction (OPC). OPC can be rule-based, model-based, or both. In rule-based OPC, the proximity effects are characterized and specific solutions are devised for specific geometric configurations. The layout design is then searched using a DRC tool or a geometric-based software engine to find these geometric configurations. Once they are found, the specific solutions are applied.

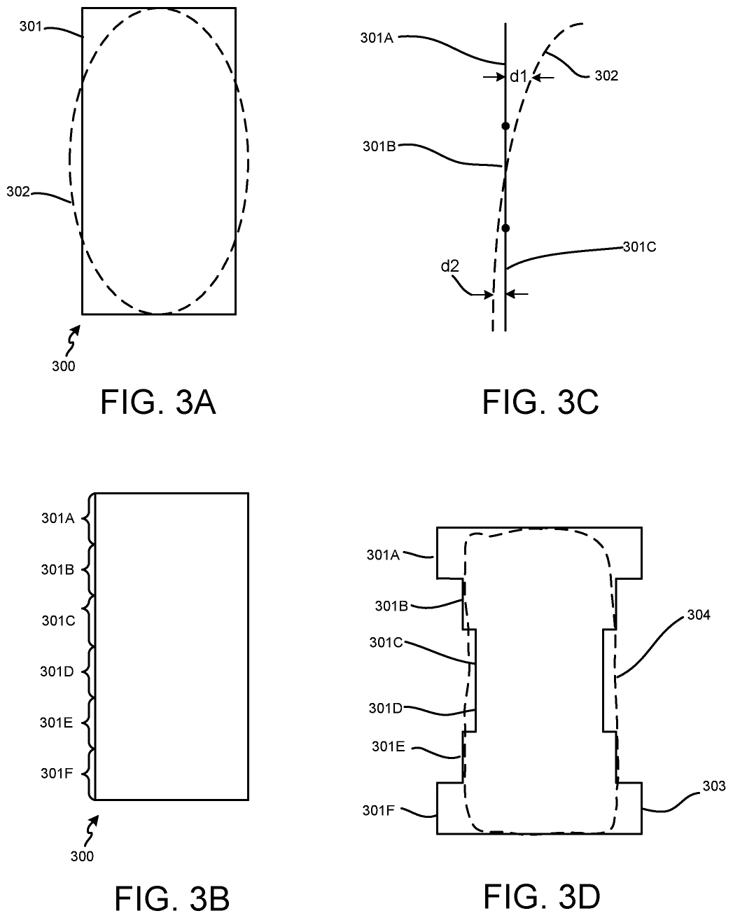

Rule-based OPC approaches work well for simple cases. For complex layout features, however, model-based OPC approaches must be employed to obtain desired results. Model-based OPC performs simulation to predict the printed image, which guides layout modifications. In a typical model-based OPC process, polygons in the layout design are divided into edge fragments to allow the desired fine motion of edge fragments. FIGS. 3A-3D illustrates an example. An edge 301 of a layout feature 300 in FIG. 3A may be fragmented into edge fragments 301A-301F as shown in FIG. 3B. The size of the edge fragments and which particular edges are to be fragmented in a given layout design depends upon the OPC process parameters, often referred to as the OPC recipe. While not all edges within a layout design are fragmented in every OPC process, these edges may also be referred to as edge fragments. Simulation is performed to obtain the predicted printed image 302 for the layout feature 300 shown in FIG. 3A. This simulated image is compared to the target image. Typically, this comparison is done at each edge fragment. For example, as shown in FIG. 3C, the target image is a distance d1 away from the simulated image at the edge fragment 301A, the target image is a distance d2 away from the simulated image at the edge fragment 301C, while the target image intersects the simulated image at the edge fragment 301B. The distances between the target image and the simulated image are often referred to as edge placement error (EPE).

Next, the edge fragments are individually moved or adjusted in order to enable the simulated image for the resulting mask to reproduce the target image as much as possible. For example, as shown in FIG. 3D, the edge fragments 301A and 301F are displaced in a direction away from the layout feature 300, in an effort to widen the corresponding portion of the image that would be produced by the resulting mask. Similarly, the edge fragments 301C and 301D are displaced in a direction toward the layout feature 300, in an effort to narrow the corresponding portion of the image that would be produced by the resulting mask. Next, the image that would be produced by a mask using the displaced edge fragments is simulated, and the new simulated image is compared with the target image, and the edge placement error for each edge fragment is computed.

This process of moving the edge fragments, simulating the image that would be produced using the moved edge fragments, and comparing the simulated image to the target image may be repeated a number of times. Each cycle of moving edge fragments and comparing the new simulated image to target image is referred to as an iteration of the OPC process. Typically, edge fragments moved during a given iteration, and the distance the edge fragments are displaced, are determined based upon the edge placement error. For example, because d1 is larger than d2 in FIG. 3C, a subsequent iteration of the optical proximity correction process may move edge fragment 301A a greater amount than edge fragment 301C.

The movement value for each edge fragment, often referred to as edge adjustment values or edge displacement values, may be the edge placement error multiplied by a constant factor (feedback factor). This feedback factor may be location dependent or edge type dependent based on the OPC recipe. Methods that consider correlations between neighboring edge fragments such as those described in U.S. Pat. Nos. 8,910,098 and 8,881,070, which are incorporated herein by reference, may also be employed to derive the movement value (referred to as cross-MEEF (mask error enhancement factor)-based methods).

The OPC iteration process continues until the simulated image is sufficiently similar to the target image (e.g., both d1 and d2 are smaller than a threshold value), or until it is determined that the displacements of the edge fragments already have converged on locations where no further movement of the edge fragments will improve the simulated image. Once the final positions of the edge fragments are determined in the layout design data, as shown in FIG. 3D, a modified mask feature 303 can be created from the corrected layout design data. As shown in FIG. 3D, the image 304 produced by the modified mask feature 303 should more closely correspond to the target image.

While OPC based on modifying geometric shapes can certainly correct many proximity effects, it does not address one proximity effect—the iso-dense bias problem caused by variations in focus condition. The variations in focus condition become significant when an off-axis illumination scheme (one of the three major resolution enhancement technologies) is optimized for greatest depth of focus of densely placed features. Sub-resolution assist features (SRAFs) can be inserted into the layout design to provide a dense-like environment for isolated features. SRAFs, sometimes also known as “scattered bars,” are sub-resolution features not meant to print. They must be carefully adjusted in size and position so that they never print over the needed process window. This determines the most important trade-off in SRAF generation and placement: making the assist features as large and dense as possible in order to create a more dense-like mask pattern, but not so large or dense that they print. Just like the edge-adjustment-based OPC approach, there are rule-based SRAF and model-based SRAF methods. The SRAF insertion is typically performed before or during the edge-adjustment-based OPC process.

Optical Proximity Correction Tool

Inverse lithography, sometimes referred to as extreme OPC, inverse OPC, or pixOPC, has been explored for optical proximity correction. Unlike conventional OPC techniques, an inverse calculation is made to arrive at the mask pattern that will supply the desired wafer image and process window given a target wafer shape and models of the lithographic optics. Inverse lithography treats optical proximity correction as a constraint optimization problem over the domain of pixilated masks. The constrained optimization problem may be stated as finding the mask m=m(x,y) that minimizes an objective function G that expresses a deviation of the image intensity I(x,y) from the threshold constant T along the target contours Cᵢ of the frame. An analytical representation of the gradient of the objective function may be found and fast Fourier transformation may be used to quickly calculate it.

The patterns derived by inverse lithography tends to be curvilinear because the lithographic optics is a band-limited system. However, inverse lithography is a relatively rigorous computational approach to determining the mask shapes that will produce the desired on-wafer results. As a result, inverse lithography tends to be computational intensive. With the present inverse lithographic techniques, the cost may not be justified for full-chip designs except for dealing with small patterns such as hot spot repairs and OPC on shapes in a memory cell.

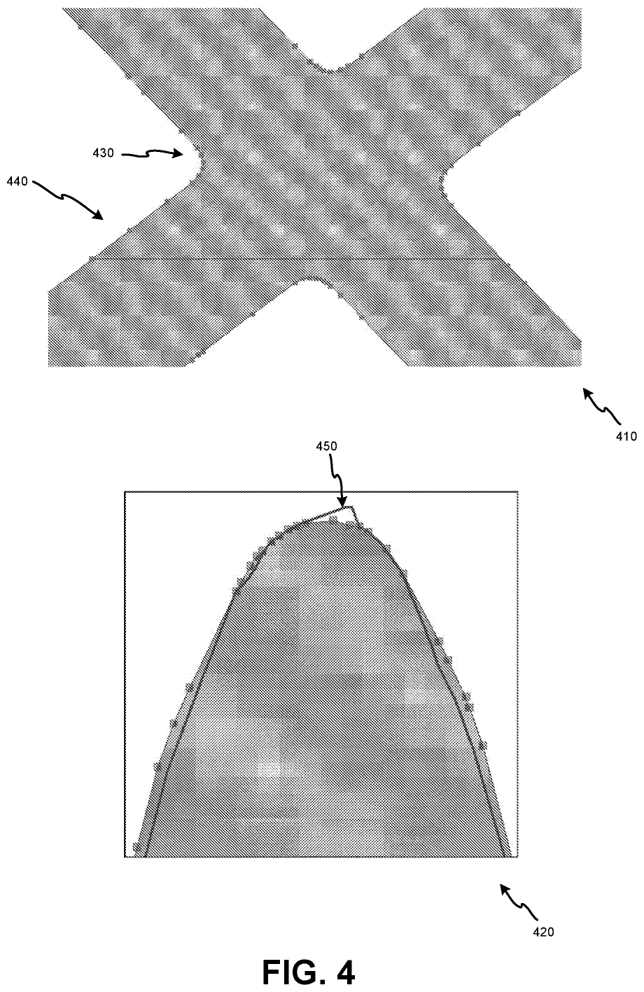

Another potential approach to performing OPC on curvilinear patterns is to use short straight line fragments to approximate curved boundary lines. FIG. 4 illustrates two curvilinear shapes 410 and 420 of which the boundary lines are fragmented. The fragmenting points on the boundary lines are indicated by dots in the figure. Straight line segments connected the neighboring dots are used to approximate the boundary lines. As can be seen in the figure, the straight line fragments associated with the boundary line segments having large curvatures are significantly shorter than with the boundary line segments having small curvatures (e.g., comparing those in location 430 with in location 440). This presents a problem to conventional OPC techniques because short straight line fragments in those locations of large curvatures are strongly correlated during an OPC process. Adjusting one short straight line fragment impacts the adjustment of many other neighboring straight line fragments. This is because the optical proximity effects increases significantly when the feature scale is much smaller than the light wavelength. The strong correlation can lead to unwanted results such as a spike feature 450 of a modified layout feature for the curvilinear shape 420.

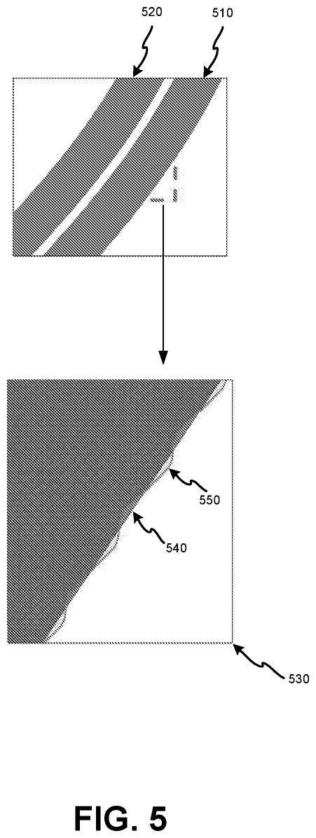

Silicon photonics features usually are not very small compared to the light wavelength. The correlation problem thus may not be significant. Using straight line segments (being parallel to either the x axis or they axis of the layout design, or having a 45-degree angle from the x axis) to approximate a curved boundary line, however, can lead to a different problem—waviness. FIG. 5 illustrates an example of waviness caused by using straight line segments to approximate curved boundary lines. The figure shows target images of two waveguides 510 and 520. Boundary lines for the waveguides 510 and 520 are curved to propagate the light carrying signals. A zoom-in picture 530 for a portion of the waveguides 510 displays both a target boundary line 540 and a simulated boundary line 550 obtained after an OPC process. The apparent waviness of the simulated boundary line 550 can be a problem for the waveguides.

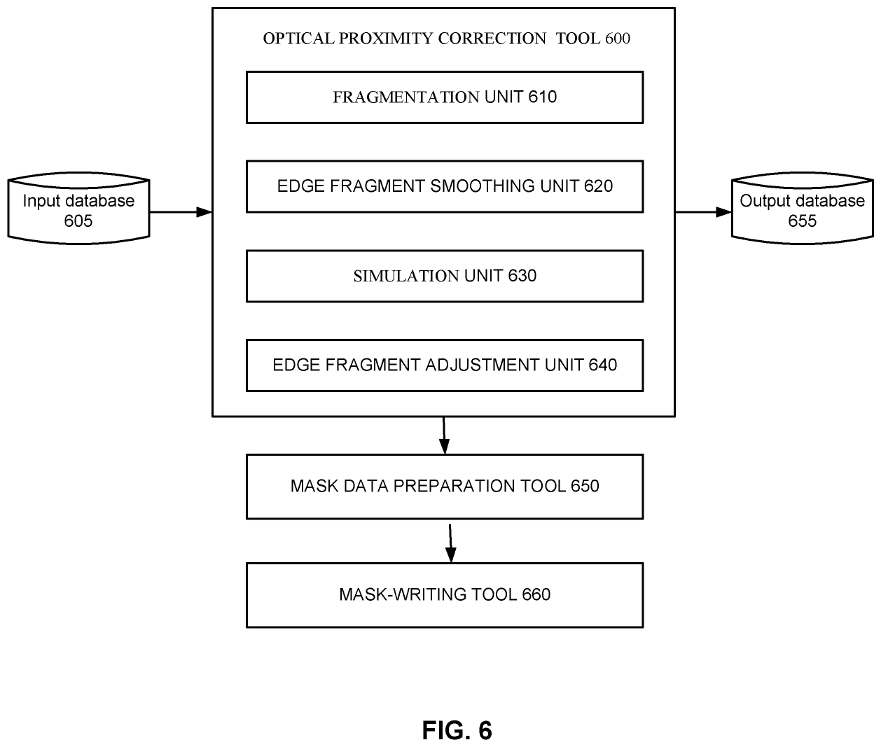

FIG. 6 illustrates an example of an optical proximity correction tool 600 that may be implemented according to various embodiments of the disclosed technology. The optical proximity correction tool 600 can be employed to perform OPC efficiently on a full-chip layout design having curvilinear patterns without causing waviness or other unwanted features. As seen in this figure, the optical proximity correction tool 600 includes a fragmentation unit 610, an edge fragment smoothing unit 620, a simulation unit 630, and an edge fragment adjustment unit 640. Some implementations of the optical proximity correction tool 600 may cooperate with (or incorporate) one or more of a mask data preparation tool 650, a mask-writing tool 660, an input database 605 and an output database 655.

As will be discussed in more detail below, the optical proximity correction tool 600 can receive a layout design from the input database 605. The fragmentation unit 610 can fragment boundary lines of layout features in the layout design into straight line fragments, which includes using some of the straight line fragments to represent fragments of curved boundary lines of the layout features. The optical proximity correction tool 600 can then generate modified layout features based on a plurality of optical proximity correction iterations. Each of the plurality of optical proximity correction iterations comprises the following operations performed by the edge fragment smoothing unit 620, the simulation unit 630, and the edge fragment adjustment unit 640, respectively. The edge fragment adjustment unit 640 can compute edge adjustment values for the straight line fragments based on edge placement errors derived from the optical proximity correction iteration immediately preceding the present optical proximity correction iteration. The edge fragment adjustment unit 640 can then adjust locations of the straight line fragments based on the determined edge adjustment values. Based on the straight line fragments on the adjusted locations, the edge fragment smoothing unit 620 can determine smooth boundary lines for the layout features. The simulation unit 630 can perform a simulation process on the layout features having the smooth boundary lines to determine a simulated image of the layout features. The edge fragment adjustment unit 640 can derive the edge adjustment errors for the straight line fragments based on comparing the simulated image with a target image of the layout features. The optical proximity correction tool 600 can determine whether to terminate the iterations based on whether the edge adjustment errors are within a predetermined range or the number of the plurality of optical proximity correction iterations is equal to a predetermined number.

After the modified layout features are generated, the optical proximity correction tool 600 can store information of the modified layout features in the output database 655. Optionally, the mask-writing tool 660 can process the modified layout features to generate mask data for a mask-writing tool to make photomasks. The mask-writing tool 660 can use the mask data to create photomasks.

As previously noted, various examples of the disclosed technology may be implemented by one or more computing systems, such as the computing system illustrated in FIGS. 1 and 2. Accordingly, one or more of the fragmentation unit 610, the edge fragment smoothing unit 620, the simulation unit 630, the edge fragment adjustment unit 640 and the mask data preparation tool 650 may be implemented by executing programming instructions on one or more processors in one or more computing systems, such as the computing system illustrated in FIGS. 1 and 2. Correspondingly, some other embodiments of the disclosed technology may be implemented by software instructions, stored on a non-transitory computer-readable medium, for instructing one or more programmable computers/computer systems to perform the functions of one or more of the fragmentation unit 610, the edge fragment smoothing unit 620, the simulation unit 630, the edge fragment adjustment unit 640 and the mask data preparation tool 650. As used herein, the term “non-transitory computer-readable medium” refers to computer-readable medium that are capable of storing data for future retrieval, and not propagating electro-magnetic waves. The non-transitory computer-readable medium may be, for example, a magnetic storage device, an optical storage device, or a solid state storage device.

It also should be appreciated that, while the fragmentation unit 610, the edge fragment smoothing unit 620, the simulation unit 630, the edge fragment adjustment unit 640 and the mask data preparation tool 650 are shown as separate units in FIG. 6, a single computer (or a single processor within a master computer) or a single computer system may be used to implement some or all of these units at different times, or components of these units at different times.

With various examples of the disclosed technology, the input database 605 and the output database 655 may be implemented using any suitable computer readable storage device. That is, either of the input database 605 and the output database 655 may be implemented using any combination of computer readable storage devices including, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable storage devices may also include magnetic cassettes, magnetic tapes, magnetic disks or other magnetic storage devices, holographic storage devices, or any other non-transitory storage medium that can be used to store desired information. While the input database 605 and the output database 655 are shown as separate units in FIG. 6, a single data storage medium may be used to implement some or all of these databases.

Process of Optical Proximity Correction for Free Shapes

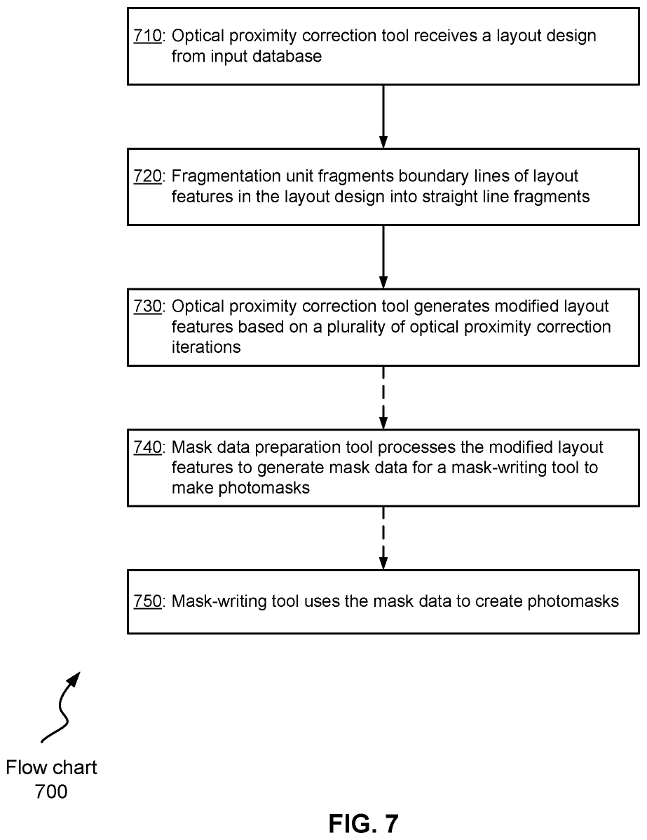

FIG. 7 illustrates a flowchart 700 showing a process of optical proximity correction that may be implemented according to various examples of the disclosed technology. For ease of understanding, methods of optical proximity correction that may be employed according to various embodiments of the disclosed technology will be described with reference to the optical proximity correction tool 600 in FIG. 6 and the flow chart 700 illustrated in FIG. 7. It should be appreciated, however, that alternate implementations of an optical proximity correction tool may be used to perform the methods of optical proximity correction illustrated by the flow chart 700 according to various embodiments of the disclosed technology. Likewise, the optical proximity correction tool 600 may be employed to perform other methods of optical proximity correction according to various embodiments of the disclosed technology.

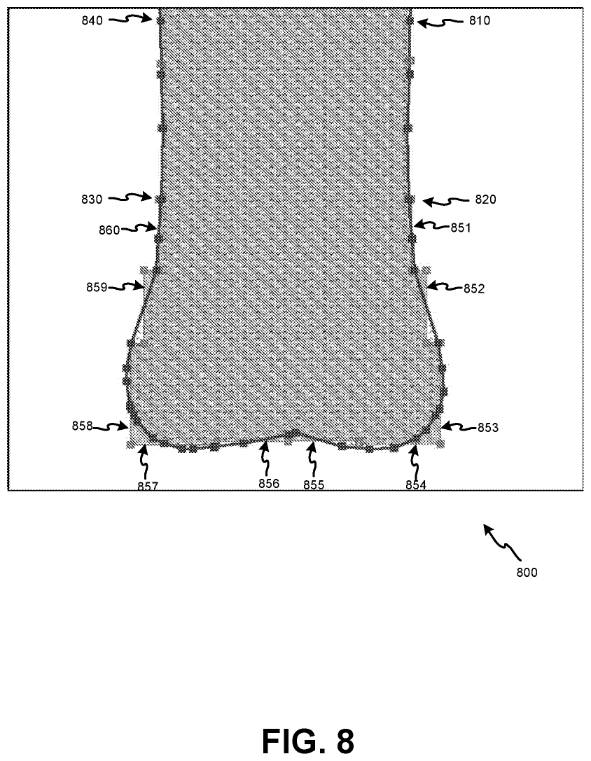

In operation 710 of the flow chart 700, the optical proximity correction tool 400 receives a layout design from the input database 705. The layout design, derived from a circuit design, may be in the GDSII standard format. The layout design can be one for a whole chip or a portion of a full-chip layout design. The layout design comprises layout features having curved boundary lines or line segments. FIG. 8 illustrates an example of part of a curvilinear layout feature 800. The layout feature 800 comprises two straight boundary line segments: one between end points 810 and 820 and the other between end points 830 and 840. The layout feature 800 also comprises a curved boundary line segment between the end points 820 and 830.

In operation 720, the fragmentation unit 610 of the optical proximity correction tool 400 fragments boundary lines of layout features in a layout design into straight line fragments. Straight boundary line segments can be divided into straight line fragments while curved boundary line segments are represented by straight line fragments. The size of straight line fragments can be dependent upon some factors such as minimum feature size of the layout design. The minimum feature size can be the gate length or the Ml (first Metal layer) half-pitch of the technology node to be used for the layout design. In some embodiments of the disclosed technology, lengths of the straight line fragments are greater than or equal to one fourth of the minimum feature size of the layout design.

With some implementations of the disclosed technology, the fragmentation unit 610 uses only straight line fragments parallel to either the x axis or the y axis of the layout design. With some other implementations of the disclosed technology, the fragmentation unit 610 may additionally use straight line fragments having angels of 45 degree and 135 degree from the x axis.

In FIG. 8, an example of a fragmentation result derived according to various embodiments of the disclosed technology being compared with a fragmentation result derived using short straight line fragments to approximate curved boundary lines (similar to FIG. 4). The two approaches produce almost the same results for the two straight boundary line segments 810-820 and 830-840 as the endpoints almost overlap. For the curved boundary line segment 820-830, however, the fragmentation by the fragmentation unit 610 leads to ten straight line fragments 851-860 while the other approach results in thirty straight line fragments. Endpoints for the latter are crowded in regions with the boundary line segments having large curvatures.

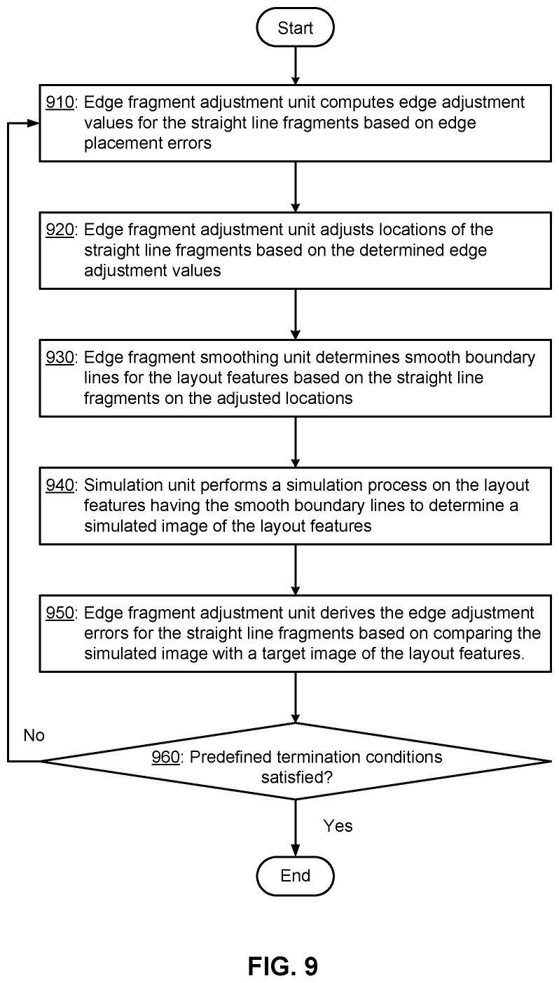

Refer back to the flowchart 700. In operation 730, the optical proximity correction tool 600 generates modified layout features based on a plurality of optical proximity correction iterations. FIG. 9 illustrates an example of the plurality of optical proximity correction iterations according to various embodiments of the disclosed technology. In operation 910, the edge fragment adjustment unit 640 computes edge adjustment values for the straight line fragments based on edge placement errors derived from the optical proximity correction iteration immediately preceding the present optical proximity correction iteration. The edge adjustment values may be obtained by multiplying the edge placement errors by a feedback factor. The feedback factor can be a constant. Alternatively, the feedback factor can be represented with a matrix including cross-MEEF to take into account correlations between neighboring straight line fragments. In operation 920, the edge fragment adjustment unit 640 can then adjust locations of the straight line fragments based on the determined edge adjustment values. The new location information of the straight line fragments can be stored.

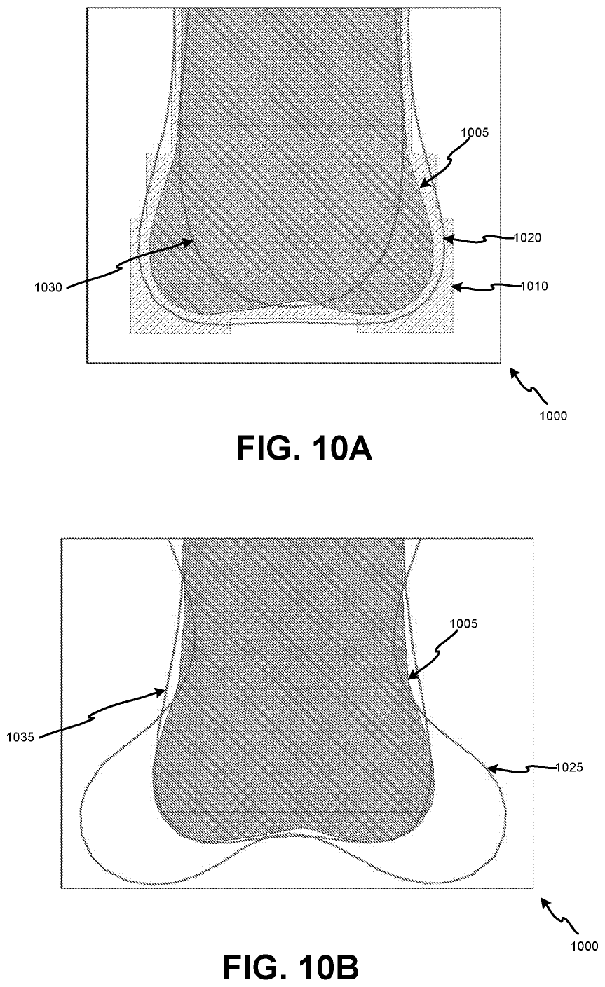

In operation 930, the edge fragment smoothing unit 620 determines smooth boundary lines for the layout features for the layout features based on the straight line fragments on the adjusted locations. Various smoothing techniques may be employed. In some embodiments of the disclosed technology, the edge fragment smoothing unit 620 employs a Gaussian convolution technique. A function representing a stair-step contour formed by the straight line fragments can be convoluted with a Gaussian weight function. The Gaussian weight function acts like a spatial filter, replacing a line formed by stair steps with a smoothed curve. The parameters of the Gaussian weight function can be selected by the user. FIG. 10A illustrates an example of a smoothing result for a layout feature 1000 derived via Gaussian convolution during an OPC iteration. In the figure, line 1005 represents the boundary line of a target image for the layout feature 1000; line 1010 represents the straight line fragments derived by fragmenting the boundary line of the layout feature 1000; and line 1020 is a smooth line obtained by applying a Gaussian convolution technique to the line 1010. In addition to Gaussian convolution, techniques based on moving average, splines, Bezier curves, least-square filtering, local regression, or other curve fitting/filtering methods can be employed.

In operation 940, the simulation unit 630 then performs a simulation process on the layout features having the smooth boundary lines to determine a simulated image of the layout features. The simulation can be based on both an optical model of the lithographic system and a resist model. Other models such as an etching model may also be used. One or more of the simulation unit 630, the fragmentation unit 610, and the edge fragment adjustment unit 640 can be implemented based on engines in a commercial OPC tool, such as those in the Calibre family of software tools available from Mentor Graphics Corporation, Wilsonville, Oregon. In FIG. 10A, line 1030 is a boundary line for a simulated image of the feature 1000 derived based on the smooth line 1020 being the boundary line for the layout feature 1000.

In operation 950, the edge fragment adjustment unit 640 derives the edge adjustment errors for the straight line fragments based on comparing the simulated image with the target image of the layout features. In FIG. 10A, the line 1030 may be compared with the line 1005 to derive an edge adjustment error for each straight line fragment on the line 1010.

In operation 960, the optical proximity correction tool 600 can determine whether to terminate the iterations based on whether the edge adjustment errors are within a predetermined range or the number of the plurality of optical proximity correction iterations is equal to a predetermined number. If the answer is no for both of the questions, the optical proximity correction tool 600 can start the next iteration. If the answer is yes for either question, the optical proximity correction tool 600 can exit the iterations, storing the information of the modified layout features in the output database 655. The information may comprise information of the smooth boundary lines for the modified layout features. FIG. 10B illustrates an example of a modified layout feature for mask preparation obtained by performing an OPC process on the layout feature 1000 according to various examples of the disclosed technology. The figure shows the line 1005 for the target image of the layout feature 1000, a final smooth line 1025 for the layout feature 1000 which is derived from the plurality of OPC iterations and can be based upon for mask writing, and a line 1035 for a simulated wafer image of the layout feature 1000 computed based on the final smooth line 1025. As can be seen, the line 1035 not only is very close to the target line 1005, but also have no waviness or other unwanted features such as spikes like the feature 450 in FIG. 4. Moreover, the OPC iterations represented by the flowchart in FIG. 9 do not include operations that are as computation intensive as in an inverse lithography process.

The optical proximity correction tool 600 may also determine process window information of the modified layout features after the plurality of optical proximity correction iterations. The simulated image obtained in operation 940 is usually an image simulated under a nominal condition. The process window information may be obtained by performing simulation under conditions deviate from the nominal condition. The optical proximity correction tool 600 can use the process window information to find hotspots, i.e., a layout pattern that may induce printability issues in lithography process. A pinching-type hotspot can result in an open or pinching defect and a bridging-type hotspot can lead to a bridge defect. The optical proximity correction tool 600 may performing a repair operation to fix some or all of the hotspots.

Refer back to the flowchart 700. In operation 740, the mask data preparation tool 650 optionally can process the modified layout features to generate mask data for a mask-writing tool to make photomasks. The mask-writing tool can be raster scan-based—either electron beams or laser beams constantly scan in a predetermined pattern. In this approach, the mask data preparation tool 650 converts the layout data into primitive shapes, which is sometimes referred to as mask data fracturing. Alternatively, the mask-writing tool can use a variable-shaped beam—a larger beam is shaped by an aperture into a primitive shape, and the image of the aperture is projected in individual “flashes” at appropriate locations. For this approach, the mask data preparation tool 650 fractures the layout design into shots of acceptable size and the appropriate stage motion instructions for creating the pattern. Additionally, the mask data preparation tool 650 may perform mask process correction (MPC). Although the photomask features are typically used in a 4× reduction system, and the feature dimensions are thus 4×larger than on the wafer, there is still need to accurately fabricate SRAF and other OPC jogs and structures that are significantly smaller. Mask process correction attempts to correct charged particle proximity effects.

In operation 750, the mask-writing tool 660 uses the mask data to create photomasks. The photomasks can be used to fabricate chips through photolithography.

### CONCLUSION

While the disclosed technology has been described with respect to specific examples including presently preferred modes of carrying out the disclosed technology, those skilled in the art will appreciate that there are numerous variations and permutations of the above described systems and techniques that fall within the spirit and scope of the disclosed technology as set forth in the appended claims. For example, while specific terminology has been employed above to refer to electronic design automation processes, it should be appreciated that various examples of the disclosed technology may be implemented using any desired combination of electronic design automation processes.

What is claimed is:

1. A method, executed by at least one processor of a computer, comprising:
fragmenting boundary lines of layout features in a layout design into straight line fragments, the fragmenting comprising using some of the straight line fragments to represent curved boundary line segments of the layout features; and
generating modified layout features based on a plurality of optical proximity correction iterations, each of the plurality of optical proximity correction iterations comprising:
computing edge adjustment values for the straight line fragments based on edge placement errors derived from an optical proximity correction iteration immediately preceding the each of the plurality of optical proximity correction iterations,
adjusting locations of the straight line fragments based on the determined edge adjustment values,
determining smooth boundary lines for the layout features based on the straight line fragments on the adjusted locations,
performing a simulation process on the layout features having the smooth boundary lines to determine a simulated image of the layout features, and
deriving the edge adjustment errors for the straight line fragments based on comparing the simulated image with a target image of the layout features.

2. The method recited in claim 1, further comprising:
processing the modified layout features to generate mask data for a mask-writing tool to make photomasks.

3. The method recited in claim 2, further comprising:
applying the mask data to the mask-writing tool to create photomasks.

4. The method recited in claim 1, wherein the determining smooth boundary lines is based on a Gaussian convolution technique.

5. The method recited in claim 1, wherein lengths of the straight line fragments are greater than or equal to one fourth of minimum feature size of the layout design.

6. The method recited in claim 1, wherein each of the straight line fragments is parallel to either an x axis or a y axis of the layout design.

7. The method recited in claim 1, wherein the computing edge adjustment values comprises multiplying the edge placement errors by a matrix including cross-mask error enhancement factors.

8. The method recited in claim 1, wherein the plurality of optical proximity correction iterations are terminated when the edge adjustment errors are within a predetermined range or a number of the plurality of optical proximity correction iterations is equal to a predetermined number.

9. One or more non-transitory computer-readable media storing computer-executable instructions for causing one or more processors to perform a method, the method comprising:
fragmenting boundary lines of layout features in a layout design into straight line fragments, the fragmenting comprising using some of the straight line fragments to represent curved boundary line segments of the layout features; and
generating modified layout features based on a plurality of optical proximity correction iterations, each of the plurality of optical proximity correction iterations comprising:
computing edge adjustment values for the straight line fragments based on edge placement errors derived from an optical proximity correction iteration immediately preceding the each of the plurality of optical proximity correction iterations,
adjusting locations of the straight line fragments based on the determined edge adjustment values,
determining smooth boundary lines for the layout features based on the straight line fragments on the adjusted locations,
performing a simulation process on the layout features having the smooth boundary lines to determine a simulated image of the layout features, and
deriving the edge adjustment errors for the straight line fragments based on comparing the simulated image with a target image of the layout features.

10. The one or more non-transitory computer-readable media recited in claim 9, wherein the method further comprises: processing the modified layout features to generate mask data for a mask-writing tool to make photomasks.

11. The one or more non-transitory computer-readable media recited in claim 10, wherein the method further comprises: applying the mask data to the mask-writing tool to create photomasks.

12. The one or more non-transitory computer-readable media recited in claim 9, wherein the determining smooth boundary lines is based on a Gaussian convolution technique.

13. The one or more non-transitory computer-readable media recited in claim 9, wherein lengths of the straight line fragments are greater than or equal to one fourth of minimum feature size of the layout design.

14. The one or more non-transitory computer-readable media recited in claim 9, wherein each of the straight line fragments is parallel to either an x axis or a y axis of the layout design.

15. The one or more non-transitory computer-readable media recited in claim 9, wherein the plurality of optical proximity correction iterations are terminated when the edge adjustment errors are within a predetermined range or a number of the plurality of optical proximity correction iterations is equal to a predetermined number.

16. A system, comprising:
one or more processors, the one or more processors programmed to perform a method, the method comprising:
fragmenting boundary lines of layout features in a layout design into straight line fragments, the fragmenting comprising using some of the straight line fragments to represent curved boundary line segments of the layout features; and
generating modified layout features based on a plurality of optical proximity correction iterations, each of the plurality of optical proximity correction iterations comprising:
computing edge adjustment values for the straight line fragments based on edge placement errors derived from an optical proximity correction iteration immediately preceding the each of the plurality of optical proximity correction iterations,
adjusting locations of the straight line fragments based on the determined edge adjustment values,
determining smooth boundary lines for the layout features based on the straight line fragments on the adjusted locations,
performing a simulation process on the layout features having the smooth boundary lines to determine a simulated image of the layout features, and
deriving the edge adjustment errors for the straight line fragments based on comparing the simulated image with a target image of the layout features.

17. The system recited in claim 16, wherein the method further comprises: processing the modified layout features to generate mask data for a mask-writing tool to make photomasks.

18. The system recited in claim 16, wherein the determining smooth boundary lines is based on a Gaussian convolution technique.

19. The system recited in claim 16, wherein lengths of the straight line fragments are greater than or equal to one fourth of minimum feature size of the layout design.

20. The system recited in claim 16, wherein each of the straight line fragments is parallel to either an x axis or a y axis of the layout design.
